(19) United States
(12) Patent Application Publication
(10) Pub. No.: US 2007/0212486 A1
(43) Pub. Date: Sep. 13, 2007

(54) Plasma Enhanced Chemical Vapor Deposition of Metal Oxide

(76) Inventors: Dmitry P. Dinega, Midland, MI (US); Christopher M. Weikart, Midland, MI (US)

Correspondence Address: THE DOW CHEMICAL COMPANY, INTELLECTUAL PROPERTY SECTION,, P. O. BOX 1967, MIDLAND, MI, 48641-1967, US

(21) Appl. No.: 11/547,461

(22) PCT Filed: May 20, 2005
(86) PCT No.: PCT/US05/17747

§ 371 Date: Oct. 4, 2006

(51) Int. Cl. C23C 16/40

(52) U.S. Cl. 427/250; 106/286.2

(57) ABSTRACT

A metal oxide coating can be applied to a substrate at a relatively low temperature and at or near atmospheric pressure by carrying a metal oxide precursor and an oxidizing agent through a corona discharge or a dielectric barrier discharge to form the metal oxide and deposit it onto to the substrate.

### BACKGROUND OF THE INVENTION

The present invention relates to plasma enhanced chemical vapor deposition of a metal oxide onto a substrate, particularly a plastic substrate.

Metal oxide films are deposited onto glass substrates for a variety of applications. For example, in U.S. Pat. No. 5,830,530, Jones describes chemical vapor deposition (CVD) coating of semiconducting SnO₂ onto a glass substrate at temperatures in the range of 250° C. to 400° C. at atmospheric or subatmospheric pressures. Similarly, McCurdy, in U.S. Pat. No. 6,238,738, describes a CVD method for laying down a tin or titanium oxide coating on a glass substrate at 630° C. and at atmospheric pressure.

In U.S. Pat. No. 6,136,162, Shiozaki et al. describes a method for depositing a transparent electroconductive zinc oxide film onto the rear surface of a photoelectric converter using magnetron sputtering under high vacuum (2.2 mtorr).

In U.S. Pat. No. 6,540,884, Siddle et al. describes a process for producing an electrically conductive low emissivity coating on a glass substrate comprising 1) depositing a reflective metal layer onto the substrate, then 2) reactive sputter depositing a metal oxide layer over the reflective metal layer in the presence of an oxygen scavenger, then 3) heat treating the substrate to 400° C. to 720° C. The metal oxide is described as being an oxide of tin, zinc, tungsten, nickel, molybdenum, manganese, zirconium, vanadium, niobium, tantalum, cerium, or titanium or mixtures thereof.

Woo, in U.S. Pat. No. 6,603,033, describes the preparation of organotitanium precursors that can be used for metal-organic chemical vapor deposition (MOCVD). The thin film of titanium oxide was described as being formed on a glass substrate that was heated to 375° C. to 475° C. Conversely, Hitchman et al., in WO 00/47797, describes the deposition of thin films of rutile titanium dioxide onto a variety of substrates including glass, sapphire, steel, aluminum, and magnesium oxide, at temperatures as low as 268° C., but at reduced pressures (1 torr).

As the art suggests, deposition of metal oxides onto temperature-resistant substrates such as glass can be carried out at relatively high temperatures without degrading the glass. However, significantly lower temperatures would be required to deposit a metal oxide onto a plastic substrate. Moreover, for practical reasons, it would further be desirable to carry out such deposition at or near atmospheric pressure. It would therefore be advantageous to discover a method for depositing a metal oxide onto a plastic substrate at a temperature below the glass transition temperature of the substrate, preferably at or near atmospheric pressure.

### SUMMARY OF THE INVENTION

The present invention addresses a need in the art by providing a method comprising the steps of 1) carrying a metal-oxide precursor through a corona discharge or a dielectric barrier discharge in the presence of an oxidizing agent to convert the precursor to a metal oxide by plasma enhanced chemical vapor deposition (PECVD), and 2) depositing the metal oxide onto a substrate.

Optionally, other precursors amenable to PECVD of organosiloxane and SiOx coating may be sequentially deposited or codeposited with metal oxides providing multilayer and/or composite compositions on the substrate.

### BRIEF DESCRIPTION OF DRAWINGS

FIG. 1 illustrates a corona discharge method of generating and depositing a metal oxide on a substrate.

FIG. 2 illustrates a dielectric barrier discharge device.

### DETAILED DESCRIPTION OF THE INVENTION

The present invention is a method for depositing a metal oxide onto a substrate using plasma enhanced chemical vapor deposition. In a first step a metal-organic precursor is carried through a corona discharge or a dielectric barrier discharge in the presence of an oxidizing agent and preferably a carrier gas. The discharge converts the precursor to a metal oxide, which is deposited on a substrate.

As used herein, the term “metal-oxide precursor” refers to a material capable of forming a metal oxide when subjected to plasma enhanced chemical vapor deposition (PECVD). Examples of suitable metal-oxide precursors include diethyl zinc, dimethyl zinc, zinc acetate, titanium tetrachloride, dimethyltin diacetate, zinc acetylacetonate, zirconium hexafluoroacetylacetonate, zinc carbamate, trimethyl indium, triethyl indium, cerium (IV) (2,2,6,6-tetramethyl-3,5-heptanedionate), and mixtures thereof. Examples of metal oxides include oxides of zinc, tin, titanium, indium, cerium, and zirconium, and mixtures thereof. An example of a particularly useful mixed oxide is indium-tin-oxide (ITO), which can be used as a transparent conductive oxide for electronic applications.

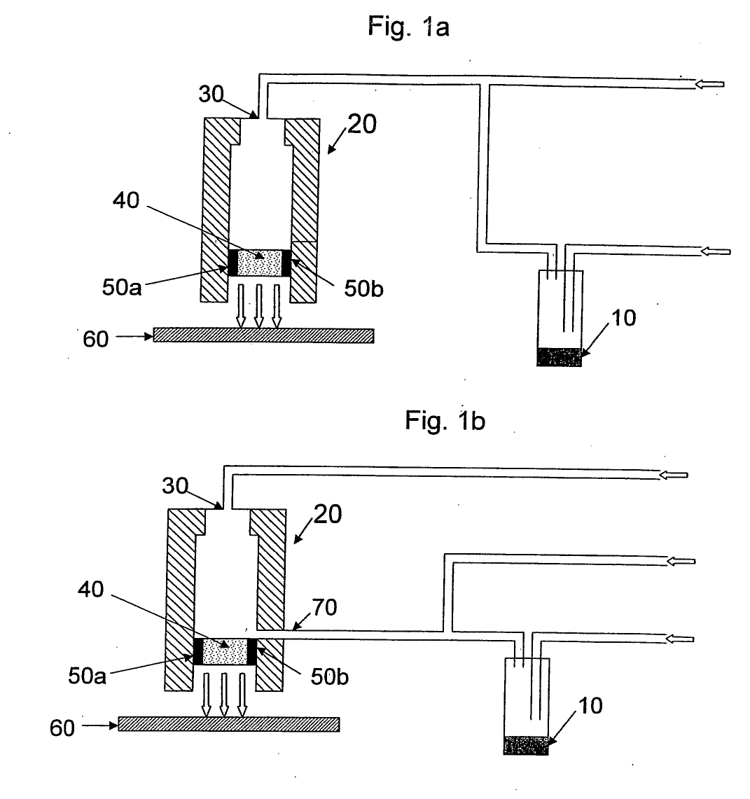

The method of the present invention can be advantageously carried out using well known corona discharge technology as illustrated in FIG. 1a. Referring now to FIG. 1a, the headspace from precursor (10), a carrier for the precursor, and the oxidizing agent is flowed into the jet (20) through a first gas intake (30) and corona discharge (40)—which breaks down gas between two electrodes 50(a) and 50(b)—to form the metal oxide, which is deposited on the substrate (60), preferably a plastic substrate that is heated to impart order thereto. If a plastic substrate is used, the plastic is advantageously maintained at a temperature near its T_{g}, preferably not exceeding 50° C. higher than its T_{g}, prior to and during the deposition of the metal oxide. The method is preferably carried out at or near atmospheric pressure, typically in the range of 700-800 torr.

The carrier for the precursor is typically nitrogen, helium, or argon, with nitrogen being preferred; the oxidizing agent is an oxygen containing gas such as O₂, N₂O, air, O₃, CO₂, NO, or N₂O₄, with air being preferred. If the precursor is highly reactive with the oxidizing agent—for example, if the precursor is pyrophoric—it is preferred to separate the oxidizing agent from the precursor, as depicted in FIG. 1b. According to this scheme, carrier and precursor are flowed through a second gas intake (70) situated just above the corona discharge (40) and the oxidizing agent is flowed through the first intake (30). Furthermore, a second carrier may be used to further dilute the concentration of the precursor prior to introduction into the jet (20). The oxidizing agent may not need to be affirmatively provided to the corona discharge or dielectric barrier discharge region if it is available to the region through the ambient air.

The corona discharge (40) is preferably maintained at a voltage in the range of about 2-20 kV. The distance between the corona discharge (40) and the substrate (60) typically varies from about 1 mm to 50 mm.

The precursor can be delivered to the jet by partially filling a container with precursor to leave a headspace and sweeping the headspace with the carrier into the jet (10). The container can be heated, if necessary, to generate the desirable vapor pressure for the precursor. Where the precursor is moisture- or air-sensitive or both, it is preferable to hold the precursor in a substantially moisture-free and oxygen-free container.

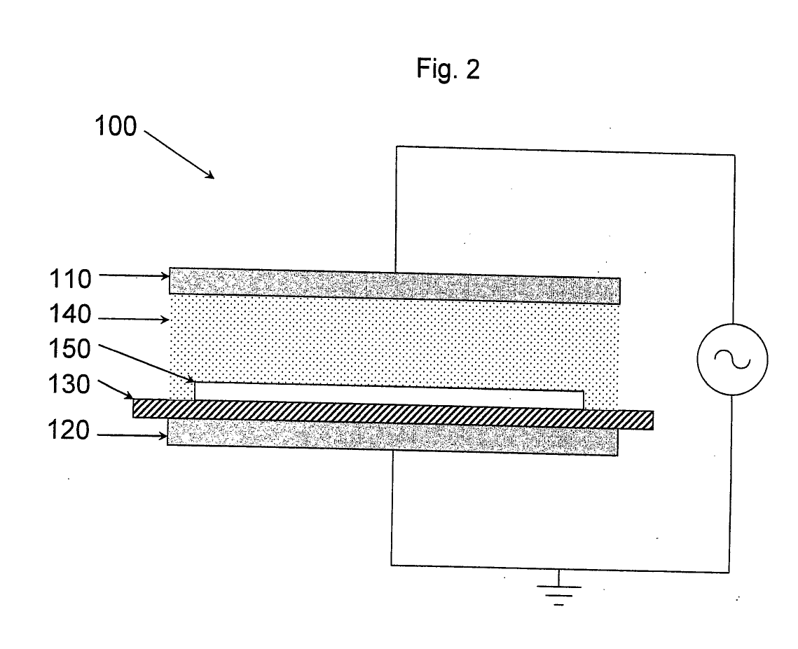

Dielectric barrier discharge, also known as “silent” and “atmospheric-pressure-glow” discharges, can also be used to carry out the process of the present invention. FIG. 2 illustrates a schematic of a dielectric barrier discharge device (100), which comprises two metal electrodes (110 and 120) in which at least one is coated with a dielectric layer (130) superposed by a substrate (150). The gap between the electrodes (110 and 120) typically ranges from 1 to 100 mm and the applied voltage is on the order of 10-50 kV. The plasma (140) is generated through a series of micro-arcs that last for about 10-100 ns and that are randomly distributed in space and time.

The concentration of the precursor in the total gas mixture (the precursor, the oxidizing agent, and the carrier gas) is preferably in the range of 10 ppm to 1% v/v. The flow rate of the precursor is preferably in the range of 0.1-10 sccm and the flow rate of the oxidizing agent is preferably in the range of 10-100 scfm (2.7×10⁵ to 2.7×10⁶ sccm). The thickness of the coating on the substrate is application dependent but is typically in the range of 10 nm to 1 μm.

The substrate is not limited but is preferably a plastic, examples of which include polycarbonates, polyurethanes, thermoplastic polyurethanes, poly(methylmethacrylates), polypropylenes, low density polyethylenes, high density polyethylene, ethylene-alpha-olefin copolymers, styrene (co)polymers, styrene-acrylonitrile copolymers, polyethylene terephthalates, and polybutylene terephthalates. The method of the present invention can provide UV blocking coatings for plastic substrates at low temperature and at or near atmospheric pressure.

The following examples are for illustrative purposes only and not intended to limit the scope of the invention.

### EXAMPLE 1—DEPOSITION OF TIN OXIDE ON A POLYCARBONATE SUBSTRATE

Dimethyltin diacetate was placed in a closed precursor reservoir and heated to 62° C. Nitrogen gas was passed through the reservoir at 3000 sccm and combined with a stream of air passed at 15 scfm (420,000 sccm). The outcoming gas line of the reservoir was heated to 70° C. The total gas mixture was passed through a PLASMA-JET® corona discharge (available from Corotec Corp., Farmington, Conn., electrode spacing of 1 cm) directed at a polycarbonate substrate. After 10 min., a clear monolithic coating of tin oxide was formed as evidenced by scanning electron microscopy and x-ray photoelectron spectroscopy (XPS).

### EXAMPLE 2—DEPOSITION OF TITANIUM OXIDE ON A POLYCARBONATE SUBSTRATE

Titanium tetrachloride was placed in a closed precursor reservoir and cooled to 0° C. Nitrogen gas was flowed through the reservoir at 600 sccm and combined with a stream of dry (TOC grade) air passed at 20 scfm (570,000 sccm). The total gas mixture was passed through the plasma jet device directed at a polycarbonate substrate. After 8 min., a clear monolithic coating of titanium oxide was formed as evidenced by scanning electron microscopy and XPS.

### EXAMPLE 3—DEPOSITION OF ZINC OXIDE ON A POLYCARBONATE SUBSTRATE

Diethyl zinc was placed in a closed precursor reservoir. Nitrogen gas was passed through the reservoir at 150 sccm and combined with another stream of nitrogen passed at 3500 sccm. This gas mixture was introduced into a stream of air plasma generated by the plasma jet device and directed onto the polycarbonate substrate. The flow rate of the air (TOC grade) was 20 scfm (570,000 sccm). After 10 min., a clear coating of zinc oxide was formed as evidenced by scanning electron microscopy and XPS.

### EXAMPLE 4—DEPOSITION OF A UV ABSORBING ZINC OXIDE ON A POLYCARBONATE SUBSTRATE

Diethyl zinc was placed in a closed precursor reservoir. Nitrogen gas was passed through the reservoir at 100 sccm and combined with another stream of nitrogen passed at 3800 sccm. This gas mixture was introduced into a stream of air plasma generated by the plasma jet device and directed onto the polycarbonate substrate. The flow rate of the air (low humidity conditioned air) was 15 scfm (570,000 sccm). The applied power to the electrodes was 720 W and the distance from jet to substrate was 20 mm. After 15 min, a clear coating of zinc oxide about 0.6 μm thick was formed on a polycarbonate sheet as evidenced by scanning electron microscopy and XPS. During deposition, the polycarbonate sheet (T_{g}=150° C.) was heated to a temperature of 180° C. to induce crystallinity in the coating, as evidenced by XRD analysis. Zinc oxide coatings were in tact after 1000 hours of QUV-B weathering tests according to ASTM G53-96. Coatings exhibited yellow Index <5 and <18% Delta Haze, 85% light transmission and a UV absorption cutoff of about 360 nm.

### EXAMPLE 5

### Deposition of Zinc Oxide Using a Dielectric Barrier Discharge on a Polycarbonate Substrate

Diethylzinc was placed in a closed reservoir. Nitrogen gas was passed through the reservoir at 150 sccm and combined with another stream of nitrogen at 60 scfm. This gas mixture was introduced downstream and mixed with air prior to exiting the electrode into the discharge zone, which contacts the polycarbonate substrate. The flow rate of air was 11357 sccm. The applied power to the electrodes was 1,000 W and a distance from electrode to substrate was about 4 mm. After 10 min, a clear coating of zinc oxide was formed on a polycarbonate film as evidenced by scanning electron microscopy and XPS.

### EXAMPLE 6

### Deposition of a SiOxCyHz or SiOx/Zinc Oxide Multilayer Coating

An organosiloxane coating similar to VPP according to patent U.S. Pat. No. 5,718,967, was deposited onto a polycarbonate substrate. The precursor tetramethyldisiloxane flowing at 6000 sccm is mixed with N2O at a flowrate of 1000 sccm. This gas mixture was introduced into a stream of nitrogen plasma generated by the plasma jet device and directed onto the polycarbonate substrate. A balance gas of nitrogen is passed at a flowrate of 25 scfm. The applied power to the electrodes was 78 W and the distance from jet to substrate was 5 mm.

A Zinc Oxide coating was deposited on top of the organosiloxane coating according to Example 4. Optionally, another organosiloxane layer was deposited on top of the Zinc Oxide layer.

What is claimed is:

1. A method comprising the steps of 1) carrying a metal-oxide precursor through a corona discharge or a dielectric barrier discharge in the presence of an oxidizing agent to convert the precursor to a metal oxide by plasma enhanced chemical vapor deposition, and 2) depositing the metal oxide onto a substrate.

2. The method of claim 1 wherein the metal-oxide precursor is carried through a corona discharge at or near atmospheric pressure.

3. The method of claim 2 wherein the substrate is a plastic that is heated to a temperature not exceeding its T_{g} by more than 50° C.

4. The method of claim 3 wherein the metal-oxide precursor is selected from the group consisting of diethyl zinc, dimethyl zinc, zinc acetate, titanium tetrachloride, dimethyltin diacetate, zinc acetylacetonate, zirconium hexafluoroacetylacetonate, trimethyl indium, triethyl indium, cerium (IV) (2,2,6,6-tetramethyl-3,5-heptanedionate), and zinc carbamate.

5. The method of claim 3 wherein the metal-oxide precursor is selected from the group consisting of diethyl zinc, titanium tetrachloride, trimethyl indium, triethyl indium, and dimethyltin diacetate.

6. The method of claim 3 wherein the oxidizing agent is selected from the group consisting of air, O₂, N₂O, CO₂, H₂O, CO, N₂O₄ and O₃ or combinations thereof.

7. The method of claim 3 wherein an inert gas carrier is used for the precursor and the oxidizing agent is present from ambient air.

8. The method of claim 2 wherein the metal oxide is selected from the group consisting of zinc oxide, titanium oxide, tin oxide, zirconium oxide, and cerium oxide.

9. The method of claim 2 wherein the metal oxide is indium-tin-oxide.

10. A method of depositing a metal oxide coating onto a plastic substrate comprising the steps of 1) carrying a metal-oxide precursor and an oxidizing agent through a corona discharge or a dielectric barrier discharge to convert by plasma enhanced chemical vapor deposition the precursor to the metal oxide, and 2) depositing the metal oxide onto the plastic substrate, wherein the discharge is maintained at or near atmospheric pressure and the substrate is heated to a temperature not exceeding 50° C. higher than its T_{g}.

11. A method of claim 9 wherein a metal oxide is deposited simultaneously or sequentially with plasma enhanced chemical vapor deposition of another material onto a plastic substrate.

12. The article made by the method of claim 11.

13. The article wherein the other material is an organosiloxane or an SiOx deposit.
